(19) United States
(12) Patent Application Publication
(10) Pub. No.: US 2022/0082933 A1
(43) Pub. Date: Mar. 17, 2022

(54) ORIGINAL PLATE AND METHOD OF MANUFACTURING THE SAME

(71) Applicant: Kioxia Corporation, Tokyo (JP)

(72) Inventors: Kaori UMEZAWA, Fujisawa Kanagawa (JP); Kosuke TAKAI, Yokohama Kanagawa (JP); Shoji MIMOTOGI, Yokohama Kanagawa (JP); Tsubasa NAITO, Kawasaki Kanagawa (JP)

(73) Assignee: Kioxia Corporation, Tokyo (JP)

(21) Appl. No.: 17/349,750

(22) Filed: Jun. 16, 2021

(30) Foreign Application Priority Data
Sep. 16, 2020 (JP) 2020-155641

(51) Int. Cl. G03F 1/76; H01L 21/027

(52) U.S. Cl. CPC G03F 1/76; H01L 21/0275

(57) ABSTRACT

In one embodiment, a method of manufacturing an original plate includes forming a first film on a first substrate, wherein an etching rate of the first film by a chemical solution including hydrofluoric acid is larger than an etching rate of the first substrate by the chemical solution. The method further includes forming a second film on the first film, wherein an etching rate of the second film by the chemical solution is smaller than the etching rate of the first film by the chemical solution. The method further includes etching the first substrate by the chemical solution using the first film and the second film as masks to form, on the first substrate, a first region having a first height, a second region having a second height different from the first height, and a first slope located between the first region and the second region.

### CROSS REFERENCE TO RELATED APPLICATION

This application is based upon and claims the benefit of priority from the prior Japanese Patent Application No. 2020-155641, filed on Sep. 16, 2020, the entire contents of which are incorporated herein by reference.

### FIELD

Embodiments described herein relate to an original plate and a method of manufacturing the same.

### BACKGROUND

When a step exists on a surface of a process target film on the substrate, a step may also be formed on a surface of a resist film formed on the process target film. In this case, the step on the resist film might adversely affect exposure of the resist film.

### BRIEF DESCRIPTION OF THE DRAWINGS

FIG. 1 is a sectional view showing a structure of an exposure apparatus of a first embodiment;

FIG. 2 is a sectional view for explaining exposure of a wafer of the first embodiment;

FIGS. 3A to 3C are sectional views showing structures of the wafer and a photomask of the first embodiment;

FIGS. 4A to 5D are sectional views showing a method of manufacturing the photomask of the first embodiment;

FIGS. 6A to 6D are sectional views showing a method of manufacturing a photomask of a comparative example of the first embodiment;

FIGS. 7A to 7D are sectional views showing a method of manufacturing a photomask of a second embodiment;

FIGS. 8A and 8B are sectional views showing two examples of the method of manufacturing the photomask of the second embodiment;

FIGS. 9A to 9C are sectional views showing structures of a wafer and a photomask of a third embodiment;

FIGS. 10A to 10C are a plan view and sectional views showing structural examples of the wafer of the third embodiment;

FIGS. 11A to 11C are a plan view and sectional views showing structural examples of the photomask of the third embodiment;

FIGS. 12A and 12B are an enlarged plan view and an enlarged sectional view showing the structures of the wafer in FIG. 10A and the photomask in FIG. 11A;

FIGS. 13A and 13B are a plan view and a sectional view showing other structural examples of the wafer and the photomask of the third embodiment;

FIG. 14 is a flowchart showing a method of manufacturing a semiconductor device of the third embodiment;

FIG. 15 is a graphic chart for explaining an advantage of the photomask of the third embodiment;

FIG. 16 is a sectional view for explaining properties of a substrate for the photomask of the third embodiment;

FIGS. 17A and 17B are diagrams for explaining properties of the substrate for the photomask of the third embodiment; and

FIG. 18 is a sectional view showing structures of the wafer and the photomask of the third embodiment.

### DETAILED DESCRIPTION

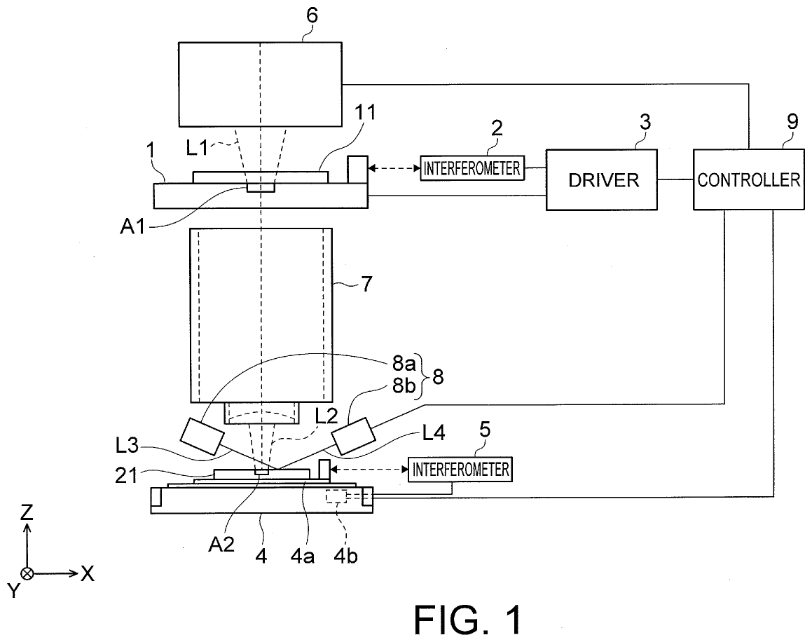

Embodiments will now be explained with reference to the accompanying drawings. In FIGS. 1 to 18, the same components are denoted by the same reference signs as the corresponding components, and redundant description thereof will be omitted.

In one embodiment, a method of manufacturing an original plate includes forming a first film on a first substrate, wherein an etching rate of the first film by a chemical solution including hydrofluoric acid is larger than an etching rate of the first substrate by the chemical solution. The method further includes forming a second film on the first film, wherein an etching rate of the second film by the chemical solution is smaller than the etching rate of the first film by the chemical solution. The method further includes etching the first substrate by the chemical solution using the first film and the second film as masks to form, on the first substrate, a first region having a first height, a second region having a second height different from the first height, and a first slope located between the first region and the second region.

### First Embodiment

FIG. 1 is a sectional view showing a structure of an exposure apparatus of a first embodiment.

The exposure apparatus in FIG. 1 includes a mask stage 1, an interferometer 2, a driver 3, a wafer stage 4, interferometer 5, a lighting unit 6, a projection unit 7, a focus sensor 8, and a controller 9. The wafer stage 4 includes a wafer chuck 4a and a driver 4b. The focus sensor 8 includes a projector 8a and a detector 8b.

FIG. 1 further shows an X direction, a Y direction, and a Z direction perpendicular to one another. Herein, the +Z direction is treated as an upward direction and a −Z direction is treated as a downward direction. Note that the −Z direction may or may not coincide with the gravity direction.

The mask stage 1 supports a photomask 11. The photomask 11 includes, for example, light-shielding patterns for use to form circuit patterns. In FIG. 1, the photomask 11 is placed on the mask stage 1. The photomask 11 is an example of the original plate.

The interferometer 2 measures position of the mask stage 1. Measurement results of the position of the mask stage 1 are outputted from the interferometer 2 to the driver 3.

The driver 3 can move the photomask 11 by moving the mask stage 1. The driver 3 includes, for example, plural motors, and can move the mask stage 1 along the X direction and the Y direction using these motors. When the driver 3 moves the mask stage 1, measurement results of the position of the mask stage 1 are fed back from the interferometer 2 to the driver 3. Based on the measurement results of the position of the mask stage 1, the driver 3 can control the position of the mask stage 1.

The wafer stage 4 supports the wafer 21. The wafer chuck 4a chucks the wafer 21 placed on the wafer stage 4. The driver 4b can move the wafer 21 by moving the wafer chuck 4a. The driver 4b includes, for example, plural motors, and can move the wafer chuck 4a along the X direction, the Y direction, and the Z direction using these motors. Furthermore, the driver 4b can adjust the tilt of the wafer chuck 4a.

The interferometer 5 measures position of the wafer chuck 4a. Measurement results of the position of the wafer chuck 4a are outputted from the interferometer 5 to the driver 4b. When the driver 4b moves the wafer chuck 4a, measurement results of the position of the wafer chuck 4a are fed back from the interferometer 5 to the driver 4b. Based on the measurement results of the position of the wafer chuck 4a, the driver 4b can control the position of the wafer chuck 4a.

The lighting unit 6 irradiates the photomask 11 with exposure light. In FIG. 1, the exposure light L1 going toward the photomask 11 from the lighting unit 6 irradiates a region A1 of the photomask 11. Consequently, the exposure light L1 is formed into light for use to form a circuit pattern on the wafer 21.

The projection unit 7 projects the exposure light transmitted through the photomask 11 onto the wafer 21. In FIG. 1, exposure light L2 going toward the wafer 21 from the projection unit 7 is projected onto a region A2 of the wafer 21. Consequently, a resist film included in the wafer 21 is exposed by the exposure light L2. The wafer 21 of the present embodiment includes a substrate, a process target film on the substrate, and a resist film on the process target film as described later. The present embodiment develops the resist film after exposure, etches the process target film using the resist film after the development as a mask, and thereby forms circuit patterns on the process target film.

The focus sensor 8 is used to measure surface topography of the wafer 21 (the resist film surface). The projector 8a irradiates the wafer 21 with detection light L3. The detector 8b detects reflected light L4, which is the detection light L3 reflected off the surface of the wafer 21, and calculates (measures) the surface topography in the wafer 21 based on detection results of the reflected light L4. Measurement results of the surface topography of the wafer 21 is outputted from the detector 8b to the controller 9.

The controller 9 controls various operations of the exposure apparatus in FIG. 1. The controller 9, for example, controls movement of the photomask 11 via the driver 3, controls movement of the wafer 21 via the driver 4b, and controls exposure of the wafer 21 through the photomask 11, via the lighting unit 6 and the projection unit 7. Furthermore, the controller 9 can receive measurement results of the surface topography of the wafer 21 from the detector 8b.

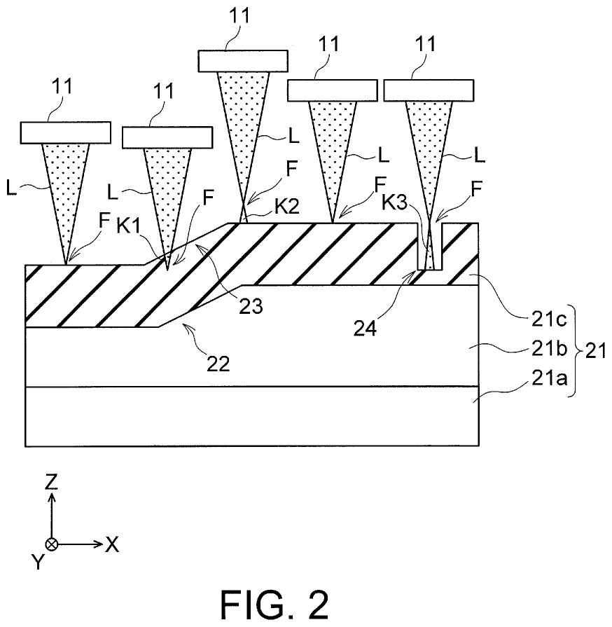

FIG. 2 is a sectional view for explaining exposure of the wafer 21 of the first embodiment.

The wafer 21 of the present embodiment includes a substrate 21a, a process target film 21b, and a resist film 21c. The substrate 21a is, for example, a semiconductor substrate such as a silicon substrate. The process target film 21b is formed on the substrate 21a. The process target film 21b may include only one type of film such as a silicon oxide film, or two or more types of film as with a laminated film made up of alternating layers of silicon oxide and silicon nitride. The process target film 21b may be formed either directly on the substrate 21a or formed on the substrate 21a via another layer. The resist film 21c is formed on the process target film 21b. The substrate 21a is an example of a second substrate.

The process target film 21b shown in FIG. 2 includes a left region having a lower top height and a right region having a higher top height. As a result, the process target film 21b has a step between the top face of the left region and the top face of the right region. The process target film 21b shown in FIG. 2 has a slope 22 between the top face of the left region and the top face of the right region, and the slope 22 makes the step smoother. The slope 22 is an example of a fourth slope.

In the present embodiment, the resist film 21c is formed on the process target film 21b. Therefore, the resist film 21c shown in FIG. 2 also includes a left region having a lower top height and a right region having a higher top height. As a result, the resist film 21c also has a step between the top face of the left region and the top face of the right region. The resist film 21c shown in FIG. 2 also has a slope 23 between the top face of the left region and the top face of the right region, and the slope 23 makes the step smoother. The slope 23 is an example of a second slope.

The wafer 21 of the present embodiment is used to manufacture, for example, a three-dimensional memory. In this case, plural memory cells of the three-dimensional memory are formed on a memory cell region of the substrate 21a, and peripheral circuitry of the three-dimensional memory is formed on a peripheral circuit region of the substrate 21a. The slopes 22 and 23 of the present embodiment are formed, for example, above a boundary between the memory cell region and peripheral circuit region of the substrate 21a.

FIG. 2 schematically shows how plural (five in this case) spots on the wafer 21 are exposed in sequence by exposure light L using a photomask 11. Furthermore, FIG. 2 shows focus positions F of the exposure light L at these spots.

An exposure apparatus (FIG. 1) of the present embodiment has a focus shift function of adjusting the focus position F in the Z direction of the exposure light L by measuring steps on a surface of the resist film 21c during exposure. However, this adjustment cannot follow every step, and consequently there occur following residual differences such as denoted by reference signs K1, K2, and K3. The following residual difference denoted by reference sign K1 occurs on the slope 23. The following residual difference denoted by reference sign K2 occurs near the slope 23. The following residual difference denoted by reference sign K3 occurs in a depression 24 formed in the resist film 21c.

When following residual differences are small, the resist film 21c can be exposed appropriately and circuit patterns can be formed with desired accuracy on the process target film 21b. However, when following residual differences are large, the resist film 21c cannot be exposed appropriately and circuit patterns cannot be formed with desired accuracy on the process target film 21b. As a result, the yield of the semiconductor device manufactured from the wafer 21 might be reduced.

When the semiconductor device is a three-dimensional memory, because a layer (e.g., a charge storage layer or a channel semiconductor layer) with a long dimension in the Z direction is often formed, large steps tend to be manufactured on the process target film 21b. Therefore, large steps tend to be manufactured on the resist film 21c as well, and yield reductions tend to occur as a result of following residual differences. Such large steps tend to be manufactured, for example, above the boundary between the memory cell region and peripheral circuit region of the substrate 21a. When circuit patterns become increasingly miniaturized and complicated, it becomes impossible to curb reductions in the yield of the semiconductor device unless following residual differences are decreased.

Thus, in the present embodiment, to solve this problem, the wafer 21 is exposed using the photomask 11 having a structure such as described later. Details of the photomask 11 of the present embodiment will be described below.

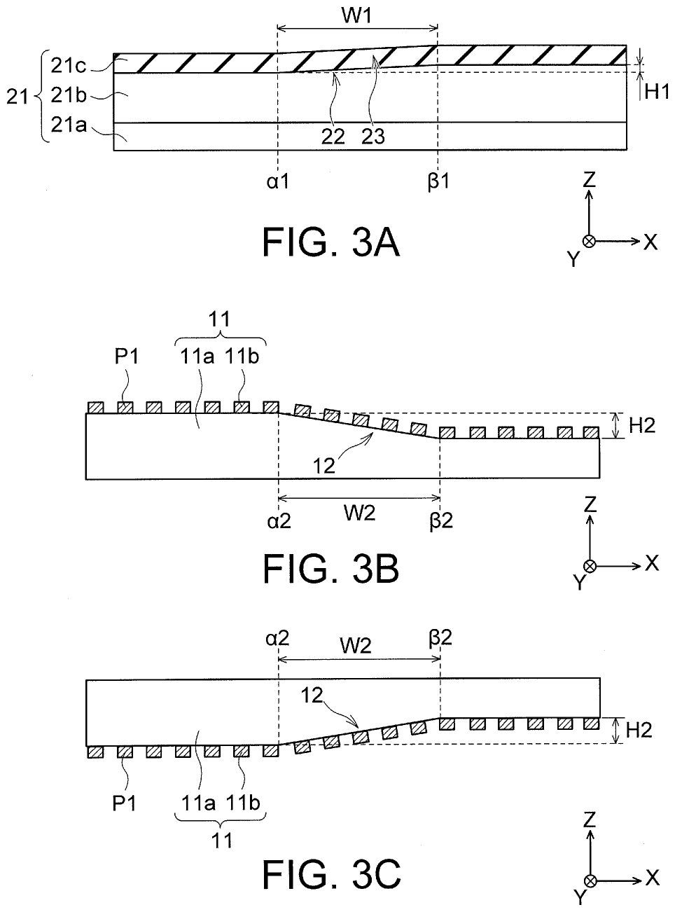

FIGS. 3A to 3C are sectional views showing structures of the wafer 21 and the photomask 11 of the first embodiment.

FIG. 3A shows the structure of the wafer 21. As described above, the wafer 21 includes the substrate 21a, the process target film 21b, and the resist film 21c. The process target film 21b includes a left region having a lower top height and a right region having a higher top height, with the slope 22 being provided between the top face of the left region and the top face of the right region. Similarly, the resist film 21c includes a left region having a lower top height and a right region having a higher top height, with the slope 23 being provided between the top face of the left region and the top face of the right region. The slopes 22 and 23 of the present embodiment are shaped to extend straight in the Y direction, but may be shaped otherwise.

FIG. 3A further shows a section α1 passing through a lower end of the slope 22 and a section β1 passing through an upper end of the slope 22. The section α1 is a boundary plane between a left region and slope 22 of the process target film 21b while the section 131 is a boundary plane between a right region of and slope 22 of the process target film 21b. According to the present embodiment, a lower end of the slope 23 is also located roughly in the section α1 and an upper end of the slope 23 is also located roughly in the section β1. Thus, the section α1 is also a boundary plane between a left region and slope 23 of the resist film 21c while the section β1 is also a boundary plane between a right region and slope 23 of the resist film 21c.

FIG. 3A further shows a width W1 of the slope 22 and a height difference H1 of the slope 22. The width W1 of the slope 22 is a distance between the lower end of the slope 22 and the upper end of the slope 22 in the X direction, which in other words is a distance between the section α1 and the section β1. The height difference H1 of the slope 22 is a distance in height between the lower end of the slope 22 and the upper end of the slope 22, which in other words is a distance between the lower end of the slope 22 and the upper end of the slope 22 in the Z direction. According to the present embodiment, a width of the slope 23 is roughly equal to the width W1 of the slope 22 and a height difference of the slope 23 is roughly equal to the height difference H1 of the slope 22. The width and height difference of the slope 23 are similar in definition to the width W1 and height difference H1 of the slope 22.

FIG. 3B shows the structure of the photomask 11. The photomask 11 includes a substrate 11a and a light-shielding film 11b. The substrate 11a is, for example, a quartz substrate. The light-shielding film 11b is formed on the substrate 11a, and includes plural light-shielding patterns P1. The light-shielding film 11b is, for example, a metal film such as a chromic film. The exposure light from the exposure apparatus (FIG. 1) of the present embodiment is transmitted through the substrate 11a and blocked by the light-shielding film 11b. The substrate 11a corresponds to a mask blank for the photomask 11. The substrate 11a is an example of a first substrate. The mask blank is an example of the original plate.

The substrate 11a shown in FIG. 3B includes a left region having a higher top height and a right region having a lower top height. As a result, the substrate 11a has a step between the top face of the left region and the top face of the right region. The substrate 11a shown in FIG. 3B has a slope 12 between the top face of the left region and the top face of the right region, and the slope 12 makes the step smoother. The slope 12 of the present embodiment is shaped to extend straight in the Y direction, but may be shaped otherwise. The light-shielding patterns P1 of the present embodiment are placed not only on the top faces of the left region and right region of the substrate 11a, but also on the slope 12 of the substrate 11a. The slope 12 is an example of a first slope. Also, the left region and right region of the substrate 11a are examples of a first region having a first height and a second region having a second height.

FIG. 3B further shows a section α2 passing through an upper end of the slope 12 and a section β2 passing through a lower end of the slope 12. The section α2 is a boundary plane between the left region and slope 12 of the substrate 11a while the section β2 is a boundary plane between the right region and slope 12 of the substrate 11a.

FIG. 3B further shows a width W2 of the slope 12 and a height difference H2 of the slope 12. The width W2 of the slope 12 is a distance between the upper end of the slope 12 and the lower end of the slope 12 in the X direction, which in other words is a distance between the section α2 and the section β2. The height difference H2 of the slope 12 is a distance in height between the upper end of the slope 12 and the lower end of the slope 12, which in other words is a distance between the upper end of the slope 12 and the lower end of the slope 12 in the Z direction.

According to the present embodiment, the width W2 of the slope 12 on the photomask 11 is set to 1/M the width W1 of the slope 22 on the wafer 21 (W2=W1/M). Furthermore, according to the present embodiment, the height difference H2 of the slope 12 on the photomask 11 is set to 1/M² the height difference H1 of the slope 22 on the wafer 21 (H2=H1/M²). The coefficient “M” is a reduction ratio used in exposing the wafer 21 using the photomask 11 on the exposure apparatus in FIG. 1. However, the width W1 and the width W2 may be set to satisfy a relationship other than W2=W1/M, and the height difference H1 and the height difference H2 may be set to satisfy a relationship other than H2=H1/M².

FIG. 3C shows the same photomask 11 as the photomask 11 shown in FIG. 3B. However, the photomask 11 shown in FIG. 3C is upside down compared to the photomask 11 shown in FIG. 3B. The photomask 11 of the present embodiment is manufactured in the state shown in FIG. 3B and used in the state shown in FIG. 3C. The slope 23 shown in FIG. 3A is inclined in such a way as to rise in the +X direction, and similarly, the slope 12 shown in FIG. 3C is inclined in such a way as to rise in the +X direction.

Note that according to the present embodiment, the section α2 of the photomask 11 corresponds in position to the section α1 of the wafer 21, and the section β2 of the photomask 11 corresponds in position to the section β1 of the wafer 21. Thus, in exposing the wafer 21 using the photomask 11, light transmitted through the position of the section α2 in the photomask 11 arrives roughly at the position of the section α1 in the wafer 21 and light transmitted through the position of the section β2 in the photomask 11 arrives roughly at the position of the section β1 in the wafer 21. In other words, the slope 23 on the resist film 21c of the wafer 21 is exposed by the light transmitted roughly through the slope 12 on the photomask 11.

Thus, on the substrate 11a of the photomask 11 of the present embodiment, the resist film 21c of the wafer 21 has the slope 12 as well as the slope 23. This makes it possible to reduce impacts of the slope 23 during exposure by the action of the slope 12 and thereby compensate for following residual differences (FIG. 2) during exposure. Thus, according to the present embodiment, the use of the photomask 11 having the slope 12 makes it possible to suitably expose the wafer 21 having the slope 23.

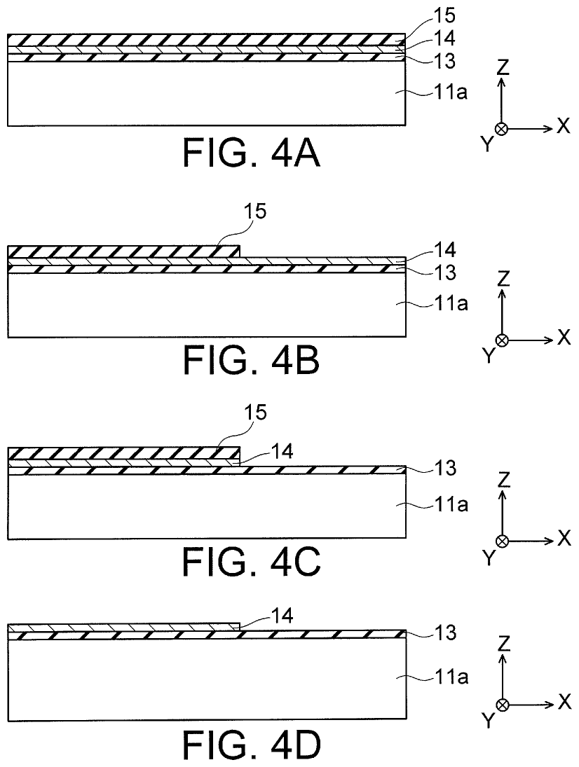

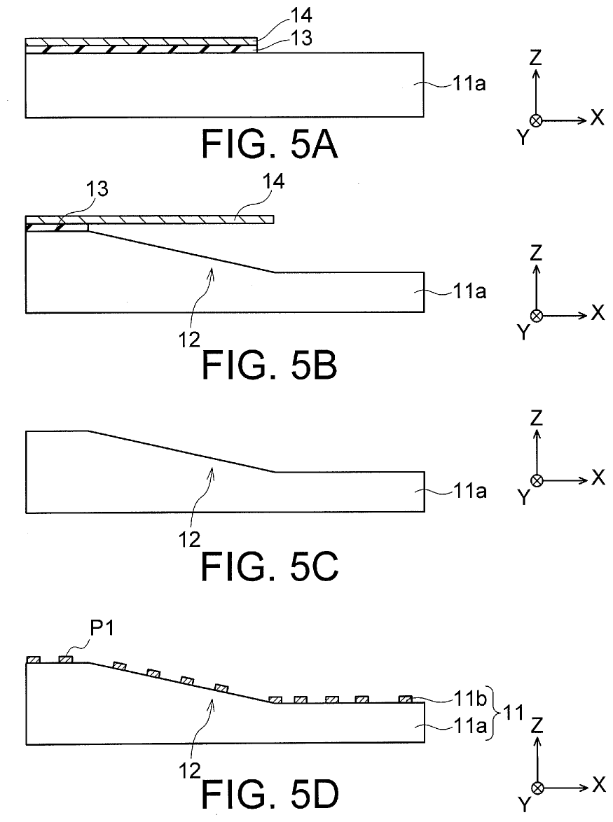

FIGS. 4A to 5D are sectional views showing a method of manufacturing the photomask 11 of the first embodiment.

First, the substrate 11a is prepared (FIG. 4A). The substrate 11a is, for example, a quartz substrate. The substrate 11a corresponds to a mask blank for the photomask 11.

Next, the substrate 11a is washed, and then a lower mask layer 13 is formed on the substrate 11a (FIG. 4A). The lower mask layer 13 of the present embodiment is a film such that an etching rate of the lower mask layer 13 by a chemical solution used in the present embodiment is larger than an etching rate of the substrate 11a by the chemical solution. The lower mask layer 13 is, for example, an oxide film such as a SiO₂ film (silicon oxide film). The lower mask layer 13 may be another film such that the etching rate of the lower mask layer 13 by the chemical solution is larger than the etching rate of the substrate 11a by the chemical solution, for example, a film including a silicon (Si) element other than a SiO₂ film (e.g., a SiON film (silicon oxynitride film)). The lower mask layer 13 can be formed, for example, by any of various methods, including CVD (Chemical Vapor Deposition), PVD (Physical Vapor Deposition), ALD (Atomic Layer Deposition), sputtering, and vapor deposition, capable of forming a uniform film. The lower mask layer 13 is an example of a first film.

Next, an upper mask layer 14 is formed on the lower mask layer 13 (FIG. 4A). The upper mask layer 14 of the present embodiment is a film such that an etching rate of the upper mask layer 14 by the chemical solution is smaller than the etching rates of the substrate 11a and the lower mask layer 13 by the chemical solution. The upper mask layer 14 is, for example, a metal film such as a Cr (chromium) film. The metal film may be formed of a single metal or formed of a metal compound (e.g., a metal oxide). The upper mask layer 14 may be another film such that the etching rate of the upper mask layer 14 by the chemical solution is smaller than the etching rates of the substrate 11a and the lower mask layer 13 by the chemical solution, for example, a film including a chromium (Cr) element, a molybdenum (Mo) element, a tungsten (W) element, a gold (Au) element, a silver (Ag) element or a platinoid element, or an organic film. The upper mask layer 14 can be formed, for example, by any of various methods, including CVD, PVD, ALD, sputtering, and vapor deposition, capable of forming a uniform film. In order not to change quality of the lower mask layer 13, desirably, formation temperature of the upper mask layer 14 is lower than formation temperature of the lower mask layer 13. The upper mask layer 14 is an example of a second film.

Next, a resist film 15 is formed on the upper mask layer 14 by being applied by a coater (FIG. 4A). In this way, the lower mask layer 13, the upper mask layer 14, and the resist film 15 are formed in sequence on the substrate 11a. The lower mask layer 13 and the upper mask layer 14 are used as hard mask layers to process the substrate 11a by etching.

Next, patterns are drawn on the resist film 15 by an EB (Electron Beam) device, and then the resist film 15 is developed (FIG. 4B). As a result, the resist film 15 is processed into a shape needed to form the above-mentioned slope 12 on the substrate 11a.

Next, the upper mask layer 14 is processed by dry etching using the resist film 15 as a mask (FIG. 4C). As a result, a pattern of the resist film 15 is transferred to the upper mask layer 14.

Next, the resist film 15 is removed (FIG. 4D). Note that the resist film 15 may be used as a mask also in the process step of FIG. 5A described later without being removed in the process step of FIG. 4D.

Next, the lower mask layer 13 is processed by dry etching using the upper mask layer 14 as a mask (FIG. 5A). As a result, a pattern of the upper mask layer 14 is transferred to the lower mask layer 13. Note that if etching by a chemical solution in the process step of FIG. 5B described later is uniform, the chemical solution may also be used in the process step of FIG. 5A. Note that if the process step of FIG. 5A and the process step of FIG. 5B are performed using the same chemical solution, these process steps may be performed as part of the same etching process.

Next, using the upper mask layer 14 and the lower mask layer 13 as masks, the substrate 11a is etched by a chemical solution (FIG. 5B). As a result, the substrate 11a is processed into a shape having a left region with a higher top height, a right region with a lower top height, and a slope 12 located between the left region and the right region as shown in FIG. 5B. The chemical solution is, for example, an aqueous solution including hydrofluoric acid (HF). The hydrofluoric acid may be any of diluted hydrofluoric acid, concentrated hydrofluoric acid, and buffered hydrofluoric acid. According to the present embodiment, diluted hydrofluoric acid at a concentration of 10% is used as the chemical solution.

The left region and slope 12 of the substrate 11a are covered with the upper mask layer 14 and the lower mask layer 13 while the right region of the substrate 11a is exposed from the upper mask layer 14 and the lower mask layer 13. Because etching by means of a chemical solution proceeds isotropically, not only the right region of the substrate 11a, but also a region around the right region of the substrate 11a are etched in the process step of FIG. 5B. As a result, the slope 12 is formed between the right region and left region of the substrate 11a.

The lower mask layer 13 of the present embodiment is a film that is etched at a larger etching rate by the chemical solution than the substrate 11a. The upper mask layer 14 of the present embodiment is a film that is etched at a smaller etching rate by the chemical solution than the substrate 11a and the lower mask layer 13. Thus, in FIG. 5B, the upper mask layer 14 is not etched much while the substrate 11a is etched greatly and the lower mask layer 13 is etched more greatly.

When the lower mask layer 13 is etched, the chemical solution enters a region from which the lower mask layer 13 has been removed. The chemical solution entering this region etches a top face of the substrate 11a. Thus, the chemical solution entering the region increases the width W2 of the slope 12 (FIG. 3B) and decreases an inclination angle of the slope 12. On the other hand, the chemical solution on the right region of the substrate 11a etches the top face of the right region of the substrate 11a and increases the height difference H2 (FIG. 3B) of the slope 12.

Thus, the width W2 of the slope 12 can be controlled by the etching rate of the lower mask layer 13 and the height difference H2 of the slope 12 can be controlled by the etching rate of the substrate 11a. As a result, the inclination angle of the slope 12 is determined by a ratio between the etching rates. For example, if the etching rate of the lower mask layer 13 is 5 times the etching rate of the substrate 11a, the inclination angle is approximately 11 degrees, and if the etching rate of the lower mask layer 13 is 10 times the etching rate of the substrate 11a, the inclination angle is approximately 5 degrees. According to the present embodiment, the height difference H2 of the slope 12 is, for example, 800 nm. Note that the etching rates of the substrate 11a and lower mask layer 13 may vary with the materials, stresses, thicknesses, and the like of the substrate 11a and lower mask layer 13. According to the present embodiment, if the materials, stresses, thicknesses, and the like are adjusted, the inclination angle of the slope 12 can be controlled and adjusted to any degree.

The chemical solution used in the process step of FIG. 5B may be a liquid including a substance other than hydrofluoric acid or may be a liquid including hydrofluoric acid and a substance other than hydrofluoric acid. The chemical solution may be, for example, an aqueous solution including hydrofluoric acid at a concentration of 6%, ammonium fluoride (NH₄F) at a concentration of 30%, and a surface-active agent.

Next, the upper mask layer 14 is removed by dry etching, and the lower mask layer 13 is removed by etching using a chemical solution (FIG. 5C). The chemical solution is, for example, an aqueous solution including diluted hydrofluoric acid or SC1.

Next, etching is done to remove streaks from a surface of the substrate 11a and round corners at an upper end and lower end of the slope 12 (FIG. 5C). As a result, the surface of the substrate 11a is smoothed. The etching is done, for example, using the chemical solution cited as an example of chemical solutions available for use in the process step of FIG. 5B. In this way, the substrate 11a (mask blank) is processed into a shape having the slope 12. Note that the etching done to remove the lower mask layer 13 and the etching done for streak removal and corner rounding may be carried out as part of the same etching process.

Next, the light-shielding film 11b is formed on the substrate 11a, and processed by dry etching (FIG. 5D). As a result, the light-shielding film 11b including plural light-shielding patterns P1 is formed on the substrate 11a. In this way, the photomask 11 including the substrate 11a and the light-shielding film 11b is formed.

Subsequently, the photomask 11 is placed on the mask stage 1 of the exposure apparatus in FIG. 1 and used to expose the wafer 21. In this way, the semiconductor device is manufactured from the wafer 21.

As described above, the lower mask layer 13 is an example of a first film and the upper mask layer 14 is an example of a second film. In the present embodiment, the resist film 15 may be used as the second film by forming the resist film 15 on the lower mask layer 13 rather than forming the upper mask layer 14 on the lower mask layer 13. For example, by using a resist film 15 resistant to the chemical solution used in the process step of FIG. 5B, it is possible to use the resist film 15 as the second film. Examples of such combinations of a resist film 15 and a chemical solution include an aqueous solution including an i-line resist film, hydrofluoric acid at a concentration of 7%, ammonium fluoride (NH₄F) at a concentration of 30%, and a surface-active agent.

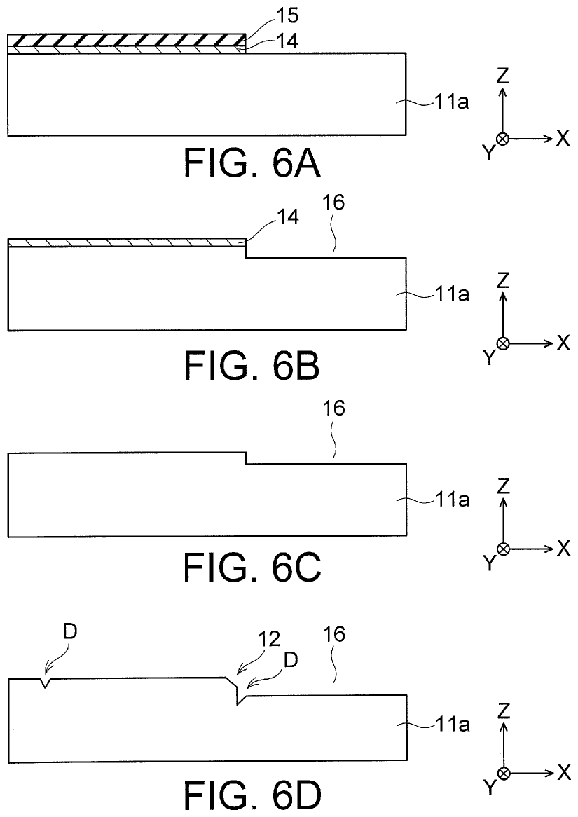

FIGS. 6A to 6D are sectional views showing a method of manufacturing a photomask 11 of a comparative example of the first embodiment.

First, a mask layer 14 similar to the upper mask layer 14 described above is formed on the substrate 11a, and the resist film 15 is formed on the mask layer 14 (FIG. 6A). According to the present comparative example, the lower mask layer 13 described above is not formed on the substrate 11a. Next, the resist film 15 is processed by EB drawing and development, and the mask layer 14 is processed by dry etching using the resist film 15 as a mask (FIG. 6A). Subsequently, the resist film 15 is removed.

Next, the substrate 11a is processed by dry etching using the mask layer 14 as a mask (FIG. 6B). As a result, a recessed portion 16 is formed in the substrate 11a by recessing the top face of the substrate 11a.

Next, the mask layer 14 is removed by dry etching (FIG. 6C). In this way, the substrate 11a (mask blank) of the present comparative example is processed into a shape having a step resulting from the recessed portion 16. Subsequently, the light-shielding film 11b is formed on the substrate 11a, thereby completing the photomask 11 of the present comparative example.

FIG. 6D shows a detailed shape of the substrate 11a shown in FIG. 6C. Because the substrate 11a of the present comparative example is processed by dry etching in the process step of FIG. 6B, the etching proceeds anisotropically in the process step of FIG. 6B. Therefore, no slope 12 is formed on the substrate 11a in the process step of FIG. 6B. Thus, after the process step of FIG. 6C, the slope 12 may be formed on the substrate 11a by CMP (Chemical Mechanical Polishing). However, the slope 12 formed by CMP will be steep as shown in FIG. 6D. Nevertheless, if CMP is not performed after the process step of FIG. 6C, scratch defects such as indicated by reference sign D will remain on the surface of the substrate 11a.

Thus, it is conceivable to do etching in the process step of FIG. 6B using a chemical solution. This makes it possible to form the slope 12 on the substrate 11a in the process step of FIG. 6B. However, the slope 12 formed in this case, will be a steep slope with an inclination angle of nearly 45 degrees. Generally, because slopes 23 on the resist film 21c of the wafer 21 are often gentle (FIG. 3A), it is difficult to compensate sufficiently for following residual differences (FIG. 2) during exposure using the photomask 11 having such a slope 12.

Thus, etching of the substrate 11a of the present embodiment is done using a chemical solution, with the substrate 11a being covered with the upper mask layer 14 and the lower mask layer 13. This allows the etching to form a gentle slope 12 on the substrate 11a.

Thus, on the substrate 11a of the photomask 11 of the present embodiment, the resist film 21c of the wafer 21 has the slope 12 as well as the slope 23. This makes it possible to reduce the impacts of the slope 23 during exposure by the action of the slope 12 and thereby compensate for following residual differences during exposure. Thus, according to the present embodiment, the use of the photomask 11 having the slope 12 makes it possible to suitably expose the wafer 21 having the slope 23.

Furthermore, the slope 12 on the substrate 11a of the present embodiment, is formed by etching using a chemical solution, with the substrate 11a being covered with the upper mask layer 14 and the lower mask layer 13. This makes it possible to form the slope 12 suitable to expose the wafer 21 having the slope 23, on the substrate 11a. For example, when the slope 23 on the wafer 21 is gentle, a gentle slope 12 can be formed on the substrate 11a.

According to the present embodiment, by exposing the wafer 21 using such a photomask 11, it is possible to increase the yield of the semiconductor device manufactured from the wafer 21.

### Second Embodiment

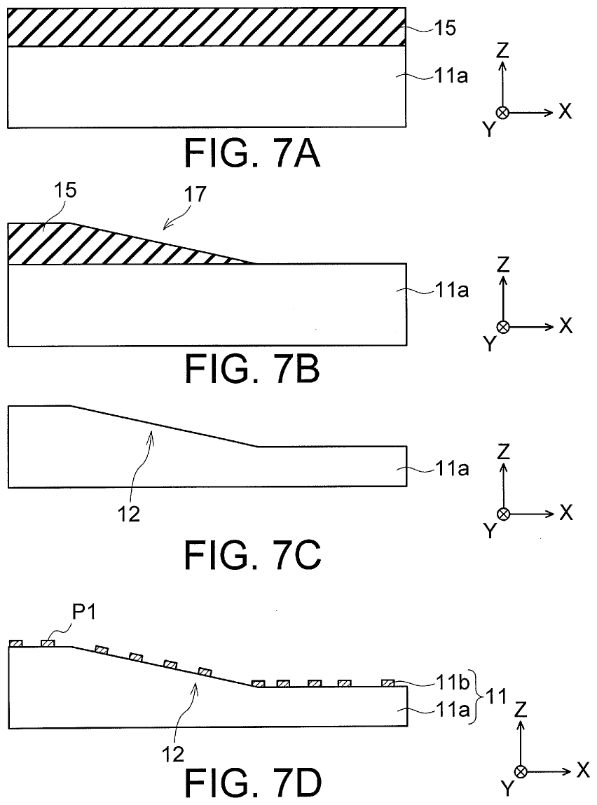

FIGS. 7A to 7D are sectional views showing a method of manufacturing a photomask 11 of a second embodiment.

First, the substrate 11a is prepared and the resist film 15 is formed on the substrate 11a (FIG. 7A). Next, by performing exposure (pattern drawing) and development by a predetermined technique, the resist film 15 is processed (FIG. 7B). As a result, the resist film 15 is processed into a shape having a slope 17 between a left region including the resist film 15 and a right region not including the resist film 15 as shown in FIG. 7B. The slope 17 is an example of a third slope. Also, the left region including the resist film 15 and the right region not including the resist film 15 are examples of a third region and fourth region. Note that as long as the resist film 15 has a slope 17, both the left region and right region may include the resist film 15.

The slope 17 of the present embodiment can be formed, for example, by drawing a pattern on the resist film 15 using a greatly blurred energy line and developing the resist film 15 subsequently. An example of such an energy line is a laser beam. The blurring of the energy line is an out-of-focus condition of the energy line and can be enhanced by defocusing the energy line. The slope 17 of the present embodiment can be formed, for example, by drawing a pattern on the resist film 15 by gray-scale drawing using a laser beam and developing the resist film 15 subsequently. This makes it possible to form the slope 17 in that a portion of the resist film 15 on which gray-scale drawing has been done.

Next, using the resist film 15 as a mask the substrate 11a is processed by etching (FIG. 7C). In so doing, the resist film 15 on the slope 17 disappears gradually as a result of the etching in the process step of FIG. 7C. This causes the slope 17 of the resist film 15 to be transferred to the substrate 11a. As a result, the substrate 11a is processed into a shape having a left region with a higher top height, a right region with a lower top height, and a slope 12 located between the left region and the right region as shown in FIG. 7C. The etching in the process step of FIG. 7C is, for example, dry etching. In this way, the substrate 11a (mask blank) is processed into a shape having the slope 12.

Next, the light-shielding film 11b is formed on the substrate 11a, and processed by dry etching (FIG. 7D). As a result, the light-shielding film 11b including plural light-shielding patterns P1 is formed on the substrate 11a. In this way, the photomask 11 including the substrate 11a and the light-shielding film 11b is formed.

Subsequently, the photomask 11 is placed on the mask stage 1 of the exposure apparatus in FIG. 1 and used to expose the wafer 21. In this way, the semiconductor device is manufactured from the wafer 21.

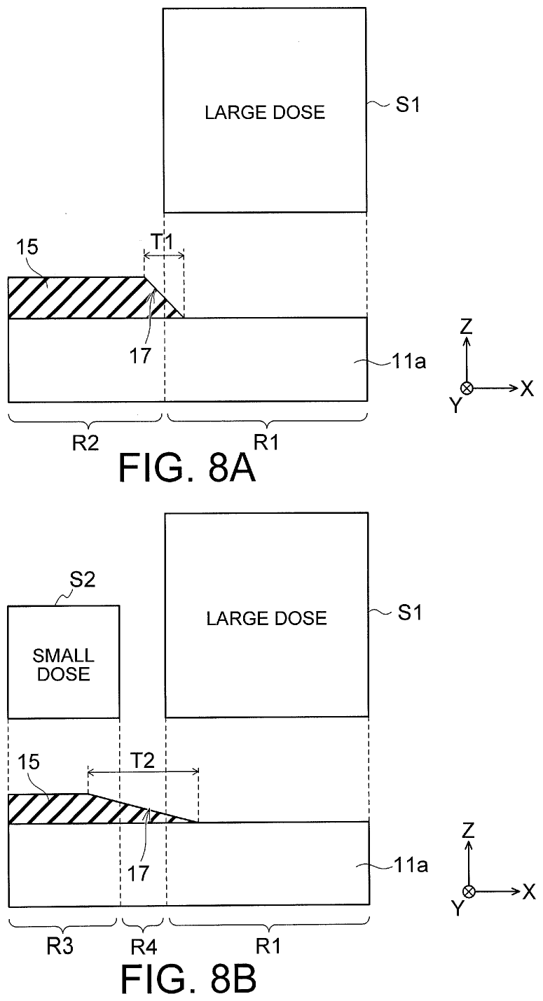

FIGS. 8A and 8B are sectional views showing two examples of the method of manufacturing the photomask 11 of the second embodiment.

FIG. 8A shows a first example of the process step of FIG. 7A. In the first example, the resist film 15 is exposed by a shot S1 of a laser beam, the resist film 15 is developed subsequently, and thereby the slope 17 is formed on the resist film 15. FIG. 8A further shows a region R1 irradiated with the shot S1, a region R2 not irradiated with the shot S1, and a width T1 of the slope 17. According to the present embodiment, the shot S1 has a cubic shape. The width T1 is, for example, approximately 1 μm.

The shot S1 of the present embodiment delivers a large dose. Thus, the resist film 15 is completely removed from many areas of the region R1 irradiated with the shot S1. On the other hand, the resist film 15 is left unremoved in many areas of the region R2 not irradiated with the shot S1. Also, near a boundary between the region R1 and the region R2, the resist film 15 is thinned by being removed partially under the influence of a blur. This makes it possible to form the slope 17 near the boundary between the region R1 and the region R2.

FIG. 8B shows a second example of the process step of FIG. 7A. In the second example, the resist film 15 is exposed by the shot S1 and a shot S2 of a laser beam, the resist film 15 is developed subsequently, and thereby the slope 17 is formed on the resist film 15. FIG. 8B further shows the region R1 irradiated with the shot S1, a region R3 irradiated with the shot S2, a region R4 located between the region R1 and the region R3, and a width T2 of the slope 17. As shown in FIG. 8B, the shot S1 and the shot S2 are different in size and separated from each other. The shots S1 and S2 are examples of a first and second shots. According to the present embodiment, the shot S2 has a cubic shape smaller than the shape of the shot S1. The width T2 is, for example, approximately 3 μm.

The shot S1 of the present embodiment delivers a large dose. Thus, the resist film 15 is completely removed from many areas of the region R1 irradiated with the shot S1. On the other hand, the shot S2 of the present embodiment delivers a small dose. Thus, in the region R3 irradiated with the shot S2, the resist film 15 is thinned by being removed partially. Similarly, in and around the region R4, the resist film 15 is thinned by being removed partially under the influence of a blur. Here, since the shot S1 has a larger dose than the shot S2, the blur of the shot S1 has a larger impact than the blur of the shot S2. As a result, the slope 17 is formed in and around the region R4, and is shaped to rise from the region R1 toward the region R3.

The photomask 11 of the present embodiment may be formed by either the method of the first example or the method of the second example. However, since the width T2 of the slope 17 in the second example is generally longer than the width T1 of the slope 17 in the first example (T2>T1), when it is desired to form a gentle slope 12 on the substrate 11a, it is desirable to adopt the method of the second example.

Thus, the present embodiment makes it possible to manufacture a photomask 11 similar in structure to the photomask 11 of the first embodiment using a method different from the method of manufacturing the photomask 11 of the first embodiment. For example, the present embodiment makes it possible to manufacture the photomask 11 without forming the lower mask layer 13 and the upper mask layer 14 on the substrate 11a.

Note that the relationships among the widths W1 and W2, the height differences H1 and H2, and the reduction ratio M of the photomask 11 and wafer 21 of the present embodiment are similar to the relationships of the first embodiment, and relationships W2=W1/M and H2=H1/M² are satisfied. However, the photomasks 11 and wafers 21 of these embodiments do not have to satisfy these relationships. A photomask 11 and a wafer 21 that do not satisfy these relationships will be described later in a third embodiment.

### Third Embodiment

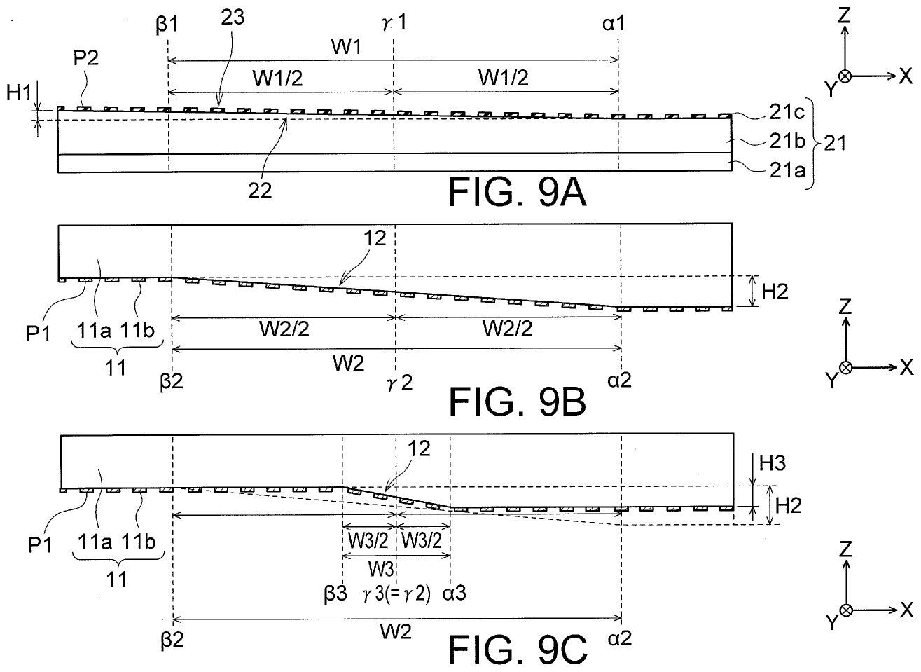

FIGS. 9A to 9C are sectional views showing structures of a wafer 21 and a photomask 11 of a third embodiment.

FIG. 9A shows the wafer 21 of the present embodiment. As with the wafer 21 in FIG. 3A, the wafer 21 in FIG. 9A includes a substrate 21a, a process target film 21b, and a resist film 21c. However, whereas FIG. 3A shows the resist film 21c before exposure and development, FIG. 9A shows the resist film 21c after exposure and development. Thus, the resist film 21c in FIG. 9A includes plural resist patterns P2 remaining after exposure and development.

In FIG. 9A, the process target film 21b includes a left region having a higher top height and a right region having a lower top height and has a slope 22 between the top face of the left region and the top face of the right region. Similarly, the resist film 21c includes a left region having a higher top height and a right region having a lower top height and has a slope 23 between the top face of the left region and the top face of the right region. The slopes 22 and 23 in FIG. 9A have shapes similar to the shapes of the slopes 22 and 23 in FIG. 3A, but whereas the slopes 22 and 23 in FIG. 3A are inclined in such a way as to rise in the +X direction, the slopes 22 and 23 in FIG. 9A are inclined in such a way as to rise in the −X direction.

FIG. 9A further shows a section α1 passing through a lower end of the slope 22, a section β1 passing through an upper end of the slope 22, and a section γ1 located at a midpoint between the section α1 and the section β1. According to the present embodiment, as with the first embodiment, a lower end of the slope 23 is also located roughly in the section α1 and an upper end of the slope 23 is also located roughly in the section β1.

FIG. 9A further shows a width W1 of the slope 22 and a height difference H1 of the slope 22. The width W1 of the slope 22 is a distance between the lower end of the slope 22 and the upper end of the slope 22 in the X direction, which in other words is a distance between the section α1 and the section β1. The height difference H1 of the slope 22 is a distance in height between the lower end of the slope 22 and the upper end of the slope 22, which in other words is a distance between the lower end of the slope 22 and the upper end of the slope 22 in the Z direction. According to the present embodiment, as with the first embodiment, a width of the slope 23 is roughly equal to the width W1 of the slope 22 and a height difference of the slope 23 is roughly equal to the height difference H1 of the slope 22. A distance between the section α1 and the section γ1 and a distance between the section β1 and the section γ1 are W1/2 as shown in FIG. 9A.

FIG. 9B shows the photomask 11 of the first embodiment for the sake of comparison with a photomask 11 of the present embodiment described later. As with the photomask 11 in FIG. 3C, the photomask 11 in FIG. 9B includes a substrate 11a and a light-shielding film 11b. The light-shielding film 11b includes plural light-shielding patterns P1.

In FIG. 9B, the substrate 11a includes a left region having a higher top height and a right region having a lower top height and has a slope 12 between the top face of the left region and the top face of the right region. The slope 12 in FIG. 9B has a shape similar to the shape of the slope 12 in FIG. 3C, but whereas the slope 12 in FIG. 3C is inclined in such a way as to rise in the +X direction, the slope 12 in FIG. 9B is inclined in such a way as to rise in the −X direction.

FIG. 9B further shows a section α2 passing through a lower end (end portion in the +X direction here) of the slope 12, a section β2 passing through an upper end (end portion in the −X direction here) of the slope 12, and a section γ2 located at a midpoint between the section α2 and the section β2.

FIG. 9B further shows a width W2 of the slope 12 and a height difference H2 of the slope 12. The width W2 of the slope 12 is a distance between the upper end of the slope 12 and the lower end of the slope 12 in the X direction, which in other words is a distance between the section α2 and the section β2. The height difference H2 of the slope 12 is a distance in height between the upper end of the slope 12 and the lower end of the slope 12, which in other words is a distance between the upper end of the slope 12 and the lower end of the slope 12 in the Z direction. A distance between the section α2 and the section γ2 and a distance between the section β2 and the section γ2 are W2/2 as shown in FIG. 9B.

In FIG. 9B, the width W2 of the slope 12 on the photomask 11 is set to 1/M the width W1 of the slope 22 on the wafer 21 (W2=W1/M). Furthermore, in FIG. 9B, the height difference H2 of the slope 12 on the photomask 11 is set to 1/M² the height difference H1 of the slope 22 on the wafer 21 (H2=H1/M²). Note that because the scale in FIG. 9A and the scale in FIG. 9B differ by M times, the width W2 is illustrated in FIGS. 9A and 9B as being equal in length to the width W1.

Note that in FIG. 9B, the section α2 of the photomask 11 corresponds in position to the section α1 of the wafer 21, and the section β2 of the photomask 11 corresponds in position to the section β1 of the wafer 21. Thus, in exposing the wafer 21 using the photomask 11 in FIG. 9B, light transmitted through the position of the section α2 in the photomask 11 arrives roughly at the position of the section α1 in the wafer 21 and light transmitted through the position of the section β2 in the photomask 11 arrives roughly at the position of the section β1 in the wafer 21. In other words, the slope 23 on the resist film 21c of the wafer 21 is exposed by the light transmitted roughly through the slope 12 on the photomask 11. Also, light transmitted through the position of the section γ2 in the photomask 11 arrives roughly at the position of the section γ1 in the wafer 21.

FIG. 9C shows the photomask 11 of the present embodiment. As with the photomasks 11 in FIGS. 3C and 9B, the photomask 11 in FIG. 9C includes a substrate 11a and a light-shielding film 11b. The light-shielding film 11b includes plural light-shielding patterns P1.

In FIG. 9C, the substrate 11a includes a left region having a higher top height and a right region having a lower top height and has a slope 12 between the top face of the left region and the top face of the right region. As with the slope 12 in FIG. 9B, the slope 12 in FIG. 9C is inclined in such a way as to rise in the −X direction.

FIG. 9C further shows a section α3 passing through a lower end of the slope 12, a section β3 passing through an upper end of the slope 12, and a section γ3 located at a midpoint between the section α3 and the section β3. FIG. 9C further shows positions of the section α2, section β2, and section γ2 for the sake of comparison with FIG. 9B.

FIG. 9C further shows a width W3 of the slope 12 and a height difference H3 of the slope 12. The width W3 of the slope 12 is a distance between the upper end of the slope 12 and the lower end of the slope 12 in the X direction, which in other words is a distance between the section α3 and the section β3. The height difference H3 of the slope 12 is a distance in height between the upper end of the slope 12 and the lower end of the slope 12, which in other words is a distance between the upper end of the slope 12 and the lower end of the slope 12 in the Z direction. A distance between the section α3 and the section γ3 and a distance between the section β3 and the section γ3 are W3/2 as shown in FIG. 9C.

In FIG. 9C, the width W3 of the slope 12 on the photomask 11 is set shorter than 1/M the width W1 of the slope 22 on the wafer 21 (W3<W1/M), and consequently shorter than the width W2 (W3<W2). Furthermore, in FIG. 9C, the height difference H3 of the slope 12 on the photomask 11 is set smaller than 1/M² the height difference H1 of the slope 22 on the wafer 21 (H3<H1/M²), and consequently smaller than the height difference H2 (H3<H2). Note that because the scale in FIG. 9A and the scale in FIG. 9C differ by M times, the width W3 is illustrated in FIGS. 9A and 9C as being shorter than the width W1.

In FIG. 9C, for example, the width W3 is set shorter than half the width W2 (W3<W2/2) and the height difference H3 is set to half the height difference H2 (H3=H2/2). As a result, the inclination angle of the slope 12 in FIG. 9C with respect to an X-Y plane becomes larger than the inclination angle of the slope 12 in FIG. 9B with respect to the X-Y plane. As an example, FIG. 9B shows a gentle slope 12 and FIG. 9C shows a steep slope 12.

Note that in FIG. 9C, the section α2 of the photomask 11 corresponds in position to the section α1 of the wafer 21, and the section β2 of the photomask 11 corresponds in position to the section β1 of the wafer 21. Thus, in exposing the wafer 21 using the photomask 11 in FIG. 9C, light transmitted through the position of the section α2 in the photomask 11 arrives roughly at the position of the section α1 in the wafer 21 and light transmitted through the position of the section β2 in the photomask 11 arrives roughly at the position of the section β1 in the wafer 21. As shown in FIG. 9C, the section α3 and the section β3 are located between the section α2 and the section R2, and the slope 12 in FIG. 9C is located between the section α3 and the section β3. Thus, the slope 23 on the resist film 21c of the wafer 21 is exposed not only by the light transmitted through the slope 12 on the photomask 11 in FIG. 9C, but also by the light transmitted between the sections α2 and α3 as well as between the sections β2 and β3, of the photomask 11 in FIG. 9C. Also, light transmitted through the position of the section γ3 in the photomask 11 arrives roughly at the position of the section γ1 in the wafer 21.

The photomask 11 of the present embodiment will be described in more detail below with continued reference to FIGS. 9A to 9C.

The substrate 11a of the photomask 11 of the first embodiment (FIG. 9B) has the slope 12 just as the resist film 21c of the wafer 21 has the slope 23. This makes it possible to reduce the impacts of the slope 23 during exposure by the action of the slope 12 and thereby compensate for following residual differences during exposure. Thus, according to the first embodiment, the use of the photomask 11 having the slope 12 makes it possible to suitably expose the wafer 21 having the slope 23.

To achieve such suitable exposure, desirably the width W2 of the slope 12 on the photomask 11 is set to 1/M the width W1 of the slope 22 on the wafer 21 (W2=W1/M) as shown in FIG. 9B. This makes it possible to expose the entire slope 23 on the resist film 21c of the wafer 21 using the light transmitted through the slope 12 on the photomask 11 and reduce the impacts of the slope 23 over the entire slope 23 by the action of the slope 12.

However, if the width W2 is set to 1/M the width W1, generally the slope 12 on the photomask 11 will become gentle. As described in the first embodiment, it is generally difficult to form a gentle slope 12.

On the other hand, according to the present embodiment, as shown in FIG. 9C, the width W3 of the slope 12 on the photomask 11 is set shorter than 1/M the width W1 of the slope 22 on the wafer 21 (W3<W1/M). This makes it possible to make the shape of the slope 12 on the photomask 11 readily formable such as making the slope 12 on the photomask 11 steep. Thus, the present embodiment makes it possible to form the slope 12 easily while reducing the impacts of the slope 23 during exposure by the action of the slope 12. When designing the shape of the slope 12 on the photomask 11 in FIG. 9C, it is desirable to increase the formability of the slope 12 while bringing the effect of the slope 12 close to the effect obtained in FIG. 9B.

The section γ3 of the slope 12 of the present embodiment is located not only at the midpoint between the section α3 and the section β3, but also at the midpoint between the section α2 and the section β2, and consequently the section γ3 of the slope 12 corresponds in position to the section γ1 of the wafer 21. Thus, in exposing the wafer 21 using the photomask 11 in FIG. 9C, light transmitted through the position of the section γ3 in the photomask 11 arrives roughly at the position of the section γ1 in the wafer 21. That is, light transmitted through the center (γ3) of the slope 12 arrives roughly at the center (γ1) of the slope 23. This makes it possible to effectively irradiate a wide range of the slope 23 with light from the slope 12 and effectively reduce the impacts of the slope 23 by the action of the slope 12.

Note that the width W3 and the height difference H3 of the photomask 11 of the present embodiment may have values different from the values described above. For example, the width W3 may be set to a value equal to or larger than half the width W2 (W3≥W2/2). Also, the height difference H3 may be set to a value other than half the height difference H2 (H3≠H2/2). Also, the section γ3 of the slope 12 of the present embodiment does not have to be located at the midpoint between the section α2 and the section β2. For example, the section γ3 may be located at a position shifted from the section γ2 as long as the section γ2 is sandwiched between the section α3 and the section β3.

The wafer 21 of the present embodiment is used to manufacture, for example, a three-dimensional memory. In this case, the slopes 22 and 23 on the wafer 21 tend to be formed, above a boundary between a memory cell region and peripheral circuit region of the substrate 21a. The slope 12 of the present embodiment is used, for example, to expose the slope 23 on the resist film 21c of the wafer 21. This makes it possible to increase the yield of the three-dimensional memory.

The photomask 11 of the present embodiment shown in FIG. 9C may be manufactured by the method described in the first embodiment or the second embodiment, or may be manufactured by another method. For example, if the slope 12 on the photomask 11 of the present embodiment is steep, the slope 12 may be formed by exposure using the shot S1 shown in FIG. 8A.

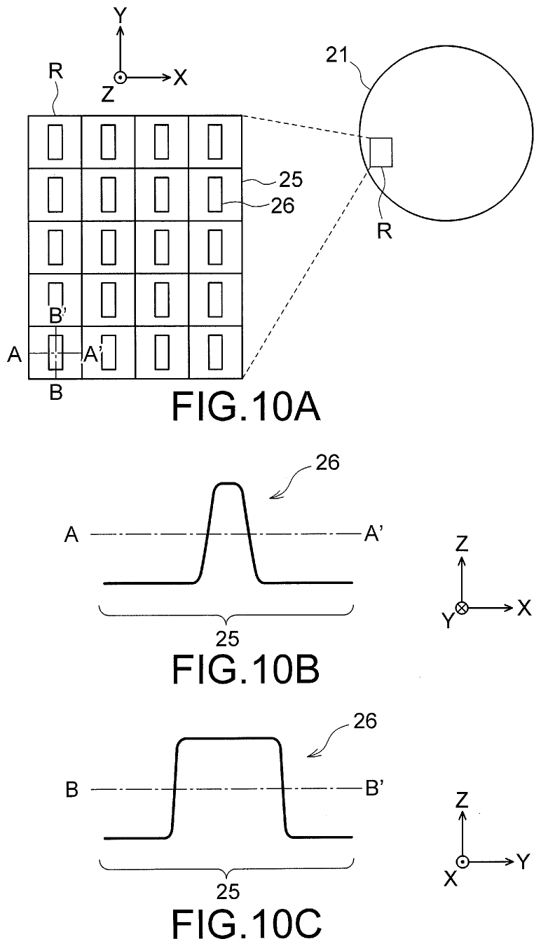

FIGS. 10A to 10C are a plan view and sectional views showing structural examples of the wafer 21 of the third embodiment.

The plan view in FIG. 10A shows an overall shape of the wafer 21 and a structure of a region R of the wafer 21. The wafer 21 in FIG. 10A is in a state after the process target film 21b and the resist film 21c are formed on the substrate 21a but before the resist film 21c is exposed and developed.

FIG. 10A shows plural (20, here) shot regions 25 in the region R and projections 26 in the respective shot regions 25. Each of the shot regions 25 is exposed by one shot during exposure of the resist film 21c. According to the present embodiment, as the shot regions 25 are scanned in the Y direction by exposure light, the resist film 21c on the shot regions 25 is exposed. The projections 26 are formed, for example, above the peripheral circuit region of the substrate 21a. As a result, lateral faces of the projections 26 are formed above the boundary between the memory cell region and peripheral circuit region of the substrate 21a. The lateral faces of the projections 26 correspond to the slopes 23 on the resist film 21c.

FIGS. 10B and 10C respectively show an X section and Y section of the projection 26 in one shot region 25. Specifically, FIG. 10B shows an X section of the projection 26 taken along line A-A′ shown in FIG. 10A and FIG. 10C shows a Y section of the projection 26 taken along line B-B′ shown in FIG. 10A. FIG. 10A shows planar shapes of the projections 26 at the height of line A-A′ shown in FIG. 10B and line B-B′ shown in FIG. 10C.

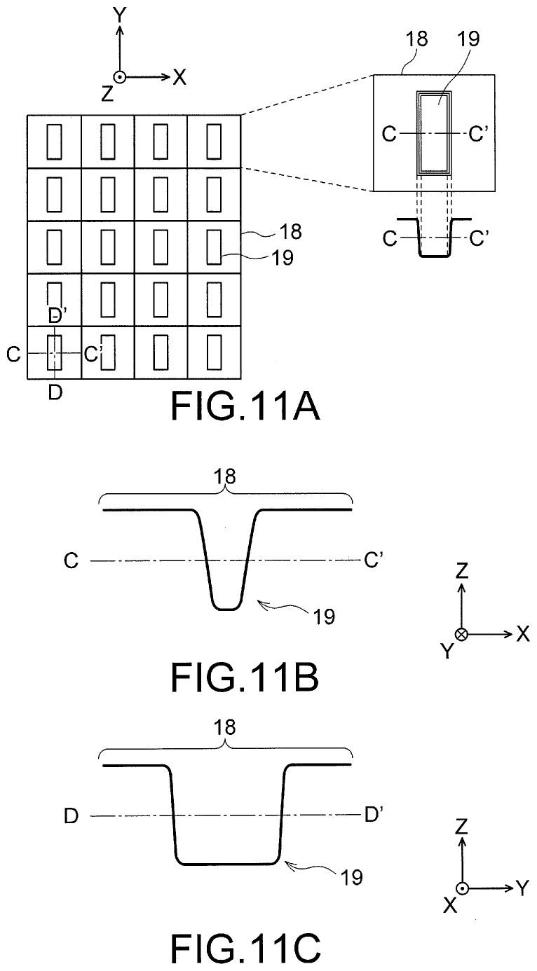

FIGS. 11A to 11C are a plan view and sectional views showing structural examples of the photomask 11 of the third embodiment.

The plan view in FIG. 11A shows plural (20, here) shot regions 18 of the photomask 11 and depressions 19 in the respective shot regions 18. The plan view in FIG. 11A further shows an enlarged view of one shot region 18. Each of the shot regions 18 is used for one shot during exposure of the wafer 21. According to the present embodiment, the shot regions 18 are irradiated with exposure light and the wafer 21 is exposed by the exposure light transmitted through the shot regions 18. For example, the exposure light transmitted through the depressions 19 is used to expose the resist film 21c above the peripheral circuit region and the exposure light transmitted through lateral faces of the depressions 19 is used to expose the resist film 21c above the boundary between the memory cell region and the peripheral circuit region. The lateral faces of the depressions 19 correspond to the slopes 12 on the substrate 11a.

FIGS. 11B and 11C respectively show an X section and Y section of the depression 19 in one shot region 18. Specifically, FIG. 11B shows an X section of the depression 19 taken along line C-C′ shown in FIG. 11A and FIG. 11C shows a Y section of the depression 19 taken along line D-D′ shown in FIG. 11A. FIG. 11A shows planar shapes of the depressions 19 at the height of line C-C′ shown in FIG. 11B and line D-D′ shown in FIG. 11C. Note that the triplet of the depression 19 in the enlarged view shown in FIG. 11A will be described later.

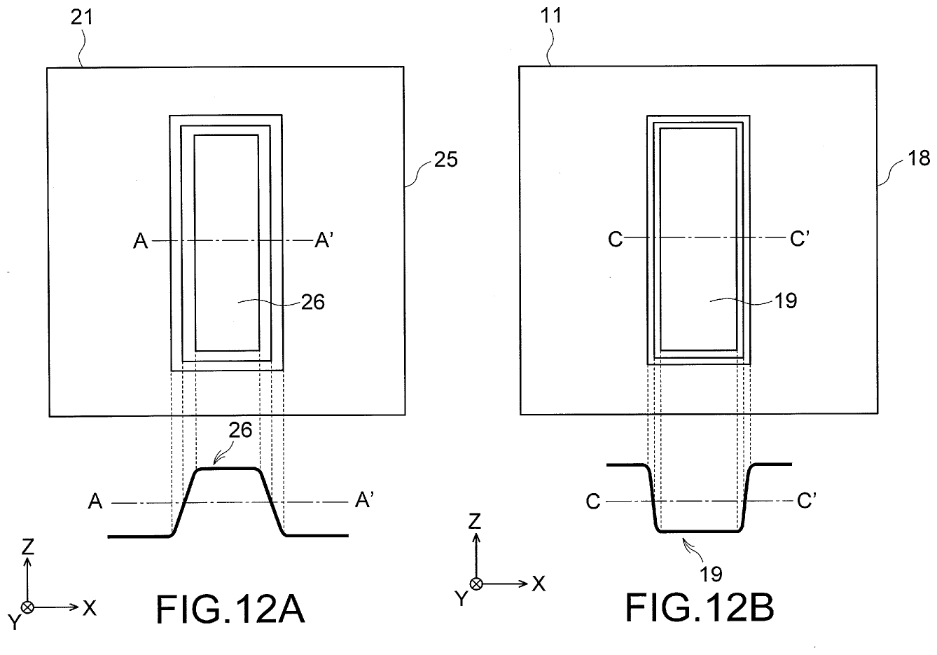

FIGS. 12A and 12B are an enlarged plan view and an enlarged sectional view showing the structures of the wafer 21 in FIG. 10A and the photomask 11 in FIG. 11A.

FIG. 12A shows a planar shape of one shot region 25 and a sectional shape of the projection 26 in the shot region 25. The triplet that represents the projection 26 shows planar shapes of the projection 26 at three different heights. Line A-A′ shown in FIG. 12A indicates the height of the center line of the triplet and the position of the sectional shape of the projection 26.

FIG. 12B shows a planar shape of one shot region 18 and a sectional shape of the depression 19 in the shot region 18. The triplet that represents the depression 19 shows planar shapes of the depression 19 at three different heights. Line C-C′ shown in FIG. 12B indicates the height of the center line of the triplet and the position of the sectional shape of the depression 19.

As shown in FIGS. 12A and 12B, the lateral faces of the projections 26 are inclined gently while the lateral faces of the depression 19 are inclined steeply. As described with reference to FIGS. 9A to 9C, according to the present embodiment, the wafer 21 having a gentle slope 23 is exposed using the photomask 11 having a steep slope 12. FIGS. 12A and 12B show the lateral faces of the depression 19 and the lateral faces of the projection 26 as examples of such slopes 12 and 23.

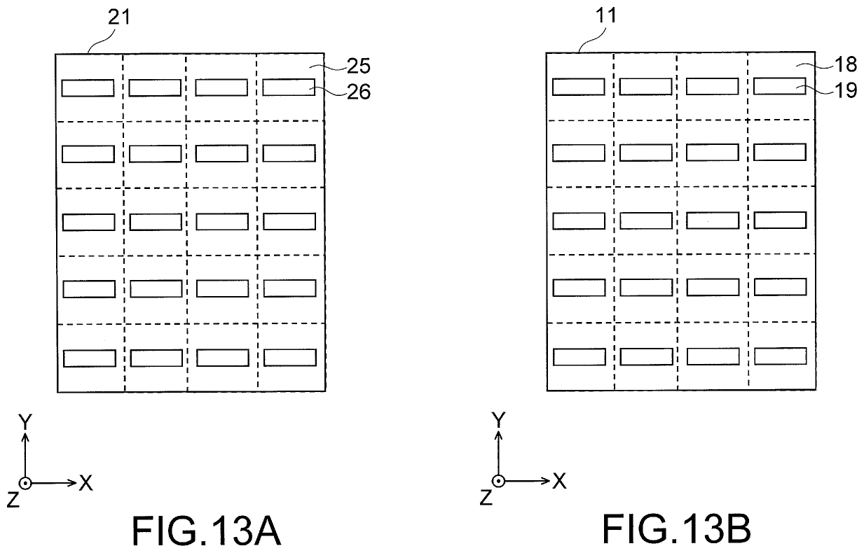

FIGS. 13A and 13B are a plan view and a sectional view showing other structural examples of the wafer 21 and the photomask 11 of the third embodiment.

The plan view in FIG. 13A shows plural (20, here) shot regions 25 of the wafer 21 and projections 26 in the respective shot regions 25. Whereas the projections 26 in FIG. 10A extend in the Y direction, the projections 26 in FIG. 13A extend in the X direction. In FIG. 13A, as the shot regions 25 are scanned in the Y direction by exposure light, the resist film 21c on the shot regions 25 is exposed.

The plan view in FIG. 13B shows plural (20, here) shot regions 18 of the photomask 11 and depressions 19 in the respective shot regions 18. Whereas the depressions 19 in FIG. 11A extend in the Y direction, the depressions 19 in FIG. 13B extend in the X direction. In FIG. 13B, the shot regions 18 are irradiated with exposure light and the wafer 21 is exposed by the exposure light transmitted through the shot regions 18.

On the wafer 21 in FIG. 10A, the projections 26 extend in the Y direction and the shot regions 25 are scanned in the Y direction. Therefore, when the wafer 21 is scanned by exposure light having a spread in the X direction, the exposure light irradiates the projections 26 and part other than the projections 26 roughly simultaneously. Thus, in this case, it is difficult to focus the exposure light.

On the other hand, on the wafer 21 in FIG. 13A, the projections 26 extend in the X direction and the shot regions 25 are scanned in the Y direction. Therefore, when the wafer 21 is scanned by exposure light having a spread in the X direction, the exposure light irradiates the projections 26 and part other than the projections 26 roughly in order. Thus, in this case, it is easy to focus the exposure light. If the structures shown in FIGS. 13A and 13B are adopted, for example, such an advantage can be enjoyed.

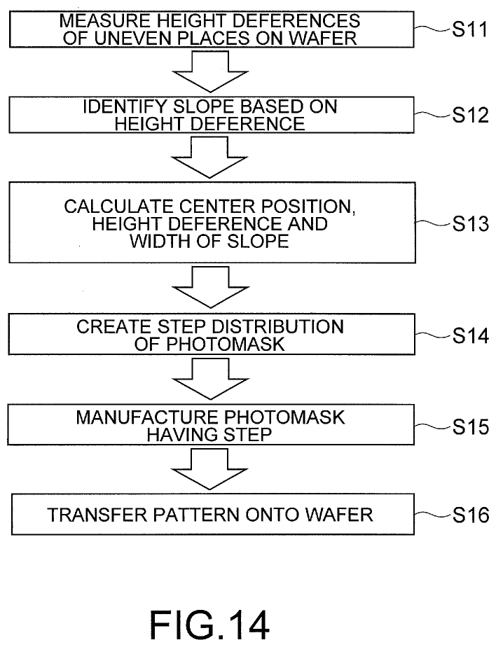

FIG. 14 is a flowchart showing a method of manufacturing a semiconductor device of the third embodiment.

First, to measure the width W1 and the height difference H1 of the slope 22 on the wafer 21, a wafer having the same structure as the wafer 21 is prepared. For example, a substrate similar to the substrate 21a is prepared, and a process target film similar to the process target film 21b is formed on the substrate. Formation of a resist film similar to the resist film 21c on the process target film is omitted. Note that instead of preparing a wafer having the same structure as the wafer 21, the wafer 21 itself may be prepared in this stage.

Next, using the prepared wafer, the height differences of uneven places on the surface of the wafer are measured (step S11). Next, based on the measured height differences, the position of a slope corresponding to the slope 22 is identified (step S12). Next, the center position (γ1), the height difference (H1), and the width (W1) of the slope is calculated (step S13).

Next, based on the calculated center position (γ1), height difference (H1), and width (W1), step distribution data of the photomask 11 used in exposing the wafer 21 is created (step S14). For example, the center position γ3, height difference H3, and width W3 of the slope 12 on the substrate 11a is calculated.

Next, the photomask 11 having the created step distribution is manufactured (step S15). For example, a substrate 11a is prepared and a slope 12 having the calculated center position γ3, height difference H3, and width W3 is formed on the substrate 11a. In this way, a mask blank (the substrate 11a) for the photomask 11 is manufactured. Furthermore, a light-shielding film 11b is formed on the substrate 11a and processed into a shape having plural light-shielding patterns P1. In this way, the photomask 11 is manufactured. The photomask 11 may be manufactured, for example, by the method of the first or second embodiment, or may be manufactured by another method.

Next, the wafer 21 is exposed using the manufactured photomask 11 (step S16). For example, a process target film 21b is formed on the substrate 21a, a resist film 21c is formed on the process target film 21b, and the resist film 21c is exposed using the photomask 11 set on the exposure apparatus in FIG. 1. Consequently, patterns on the photomask 11 are transferred to the resist film 21c. Furthermore, the exposed resist film 21c is developed and the process target film 21b is processed by etching using the developed resist film 21c as a mask. Consequently, plural resist patterns P2, which are patterns of the resist film 21c, are transferred to the process target film 21b. In this way, the semiconductor device of the present embodiment is manufactured.

Note that the center position (γ1), height difference (H1), and width (W1) used in step S14 may be values other than the values measured in steps S11 to step S13, and may be, for example, values calculated by simulations or values calculated from design values of the wafer 21.

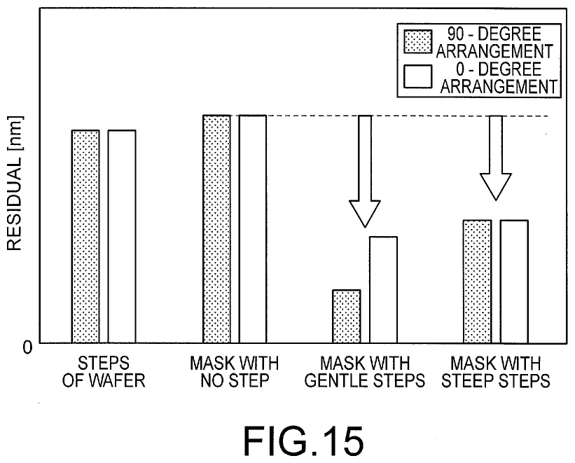

FIG. 15 is a graphic chart for explaining an advantage of the photomask 11 of the third embodiment.

FIG. 15 shows defocus residuals caused by a photomask 11 with no step (slope 12), a photomask 11 with gentle steps as in the first embodiment, and a photomask 11 with steep steps as in the third embodiment. The 90-degree arrangement involves arranging the projections 26 or the depressions 19 in the Y direction (90-degree direction) as shown in FIGS. 10A to 12B. The 0-degree arrangement involves arranging the projections 26 or the depressions 19 in the X direction (0-degree direction) as shown in FIGS. 13A and 13B.

It can be seen from FIG. 15 that if the photomask 11 with no step is used, steps on the wafer 21 become directly as defocus residuals. Also, it can be seen that if the photomask 11 with gentle steps is used, defocus residuals can be reduced greatly. Also, it can be seen that if the photomask 11 with steep steps is used, defocus residuals can be reduced to some extent. Thus, the present embodiment makes it possible to form the slope 12 easily during manufacturing of the photomask 11 while reducing the impacts of the slope 23 to some extent by the action of the slope 12 during exposure of the wafer 21.

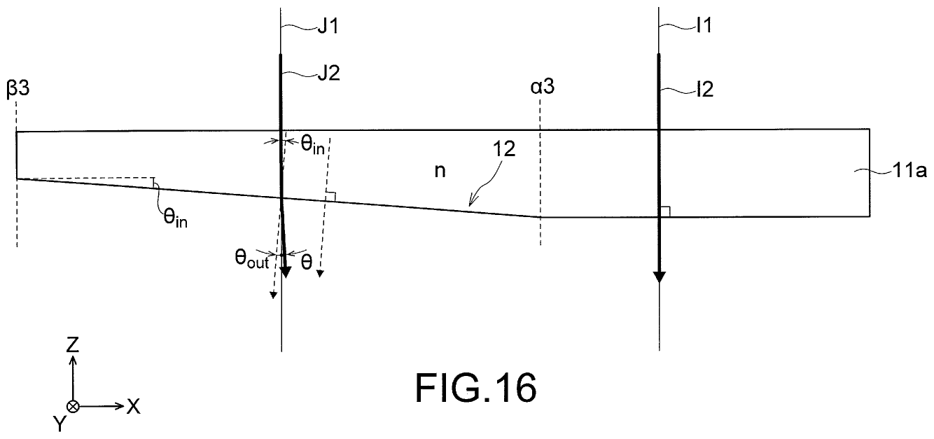

FIG. 16 is a sectional view for explaining properties of the substrate 11a for the photomask 11 of the third embodiment.

FIG. 16 shows an inclination angle gin of the slope 12 on the substrate 11a, the section α3 passing through the lower end of the slope 12, the section β3 passing through the upper end of the slope 12, and a refractive index n of the substrate 11a. For example, the substrate 11a is a quartz substrate, and the refraction index n is 1.56 when the wavelength of exposure light is 193 nm.

FIG. 16 further shows an optical axis I1 in flat part (part other than the slope 12) of the substrate 11a, exposure light I2 entering the flat portion of the substrate 11a, an optical axis J1 in sloped part (part made up of the slope 12) of the substrate 11a, and exposure light J2 entering the sloped portion of the substrate 11a. The optical axes I1 and J1 are parallel to the Z direction. Also, the exposure lights 12 and 32 travel in the −Z direction and enter a bottom face of the substrate 11a.

In the flat part, the exposure light J2 entering the bottom face of the substrate 11a exits the substrate 11a without deflection. On the other hand, in the sloped part, the exposure light I2 entering the bottom face of the substrate 11a exits the substrate 11a by deflecting an angle θ from the −Z direction of the inclination angle θin. The angle θ is given by expression (1) below.

θ=θout−θin=sin⁻¹(n×sin θin)−θin (1)

As the exposure light J2 entering the bottom face of the substrate 11a exits the substrate 11a by deflecting an angle θ, patterns transferred onto the wafer 21 are displaced.

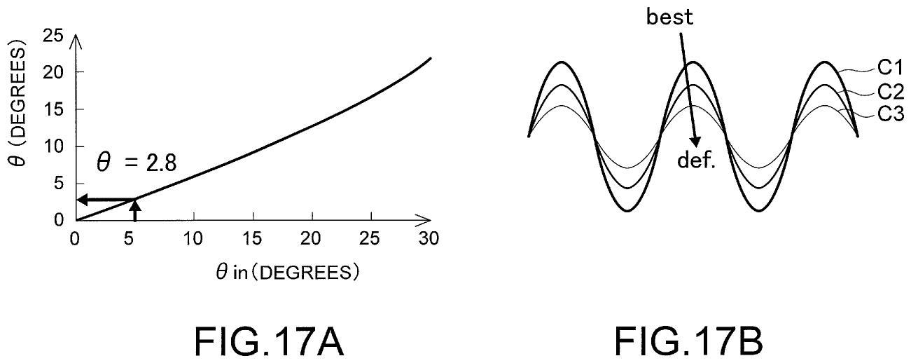

FIGS. 17A and 17B are diagrams for explaining properties of the substrate 11a for the photomask 11 of the third embodiment.

FIG. 17A shows a relationship between the inclination angle θin and the angle θ in expression (1). For example, when the inclination angle θin is 5 degrees, the angle θ is 2.8 degrees. As shown by curves C1 to C3 in FIG. 17B, when focus position is shifted from the best focus position, the displacement of the patterns transferred onto the wafer 21 increases. The displacement is given by expression (2) below.

Δx=Δz×tan {sin⁻¹(n×sin θin)−θin} (2)

In expression (2), Δz is defocus and Δx is displacement. For example, when the inclination angle θin is 5 degrees, and the defocus Δz is 50 nm, the displacement Δx is 2.45 nm.

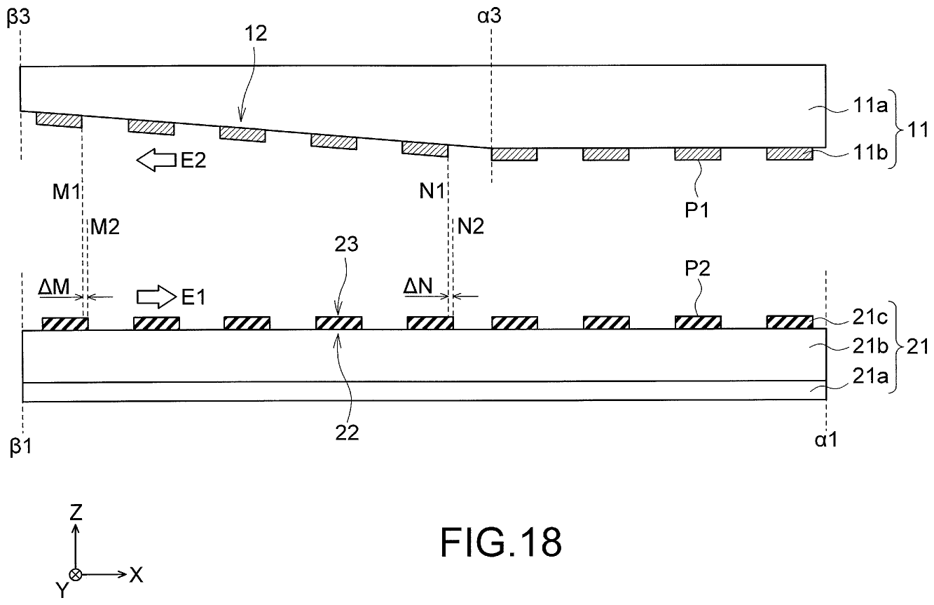

FIG. 18 is a sectional view showing structures of the wafer 21 and the photomask 11 of the third embodiment.

FIG. 18 shows the slopes 22 and 23 on the wafer 21 and the slope 12 on the photomask 11. However, to make it easy to understand displacement, the slopes 22 and 23 shown in FIG. 18 are illustrated as being parallel to the X-Y plane.

In FIG. 18, as indicated by reference signs ΔM and ΔN, the resist patterns P2 on the resist film 21c are displaced. Straight lines M1 and M2 indicate edges of corresponding light-shielding patterns P1 and resist patterns P2 in the +X direction. Since the resist patterns P2 are displaced by ΔM, the straight lines M1 and M2 are misaligned from each other. Similarly, straight lines N1 and N2 indicate edges of corresponding light-shielding patterns P1 and resist patterns P2 in the +X direction. Since the resist patterns P2 are displaced by ΔN, the straight lines N1 and N2 are misaligned from each other. In this way, the resist patterns P2 shown in FIG. 18 are displaced in the direction of an arrow E1.

Thus, in manufacturing the photomask 11 of the present embodiment, the light-shielding patterns P1 may be formed in such a way as to be shifted in position from design values in the direction of an arrow E2. For example, if it is expected that a certain resist pattern P2 will be displaced by Δx in the +X direction, the corresponding light-shielding pattern P1 may be formed in such a way as to be shifted Δx in position from the design value in the −X direction. That is, the position of the corresponding light-shielding pattern P1 may be corrected in this way.

As can be seen from expression (2), the displacement of the resist patterns P2 changes in magnitude with the inclination angle θin of the slope 12 on the substrate 11a. Thus, in manufacturing the photomask 11 of the present embodiment, the light-shielding patterns P1 may be formed in such a way as to be shifted in position from the design values by a distance based on the inclination angle θin. This makes it possible to effectively reduce displacement of the resist patterns P2.

Note that in manufacturing the photomask 11 of the present embodiment, in addition to shifting the light-shielding patterns P1 in position from design values, widths of the light-shielding patterns P1 in the X direction may be corrected from design widths. This makes it possible to more effectively reduce displacement of the resist patterns P2. Also, when the displacement of the resist patterns P2 changes with a variable other than the inclination angle gin related to the shape of the slope 12 the positions and widths of the light-shielding patterns P1 may be corrected according to the variable.

Thus, the slope 12 on the photomask 11 of the present embodiment is formed to have the width W3 smaller than the width W2 of the slope 12 on the photomask 11 of the first embodiment and the second embodiment. Also, the slope 12 on the photomask 11 of the present embodiment is formed to have the height difference H3 smaller than the height difference H2 of the slope 12 on the photomask 11 of the first embodiment and the second embodiment. This makes it possible to make the shape of the slope 12 on the photomask 11 readily formable such as making the slope 12 on the photomask 11 steep. Thus, the present embodiment makes it possible to form the slope 12 easily while reducing the impacts of the slope 23 during exposure by the action of the slope 12.

Note that the method of processing the mask blank and the method of manufacturing the photomask 11 of the first to third embodiments may be applied to processing or manufacturing of original plates other than mask blanks and the photomasks 11. An example of the original plate is a template for nano-printing.

These embodiments may be embodied as the following manners.

(1) A method of manufacturing an original plate comprises preparing a first substrate provided with a first slope; and forming, on the first slope, a light-shielding film including a plurality of light-shielding patterns.

(2) A method of manufacturing a semiconductor device, comprises preparing an original plate including a first substrate provided with a first slope, and a light-shielding film provided on the first substrate and including a plurality of light-shielding patterns; exposing a resist film formed on a second substrate via a process target film using the photomask; and processing the process target film using the resist film as a mask.

(3) In the method of (2), the original plate is used for exposing a wafer that includes the second substrate, the process target film provided on the second substrate and having a fourth slope, and the resist film provided on the process target film and having a second slope.

(4) In method of (3), the first slope has a width smaller than 1/M a width of the fourth slope where M is a reduction ratio of the exposure.

While certain embodiments have been described, these embodiments have been presented by way of example only, and are not intended to limit the scope of the inventions. Indeed, the novel plates and methods described herein may be embodied in a variety of other forms; furthermore, various omissions, substitutions and changes in the form of the plates and methods described herein may be made without departing from the spirit of the inventions. The accompanying claims and their equivalents are intended to cover such forms or modifications as would fall within the scope and spirit of the inventions.

1. A method of manufacturing an original plate, comprising:
forming a first film on a first substrate, an etching rate of the first film by a chemical solution including hydrofluoric acid being larger than an etching rate of the first substrate by the chemical solution;
forming a second film on the first film, an etching rate of the second film by the chemical solution being smaller than the etching rate of the first film by the chemical solution; and
etching the first substrate by the chemical solution using the first film and the second film as masks to form, on the first substrate, a first region having a first height, a second region having a second height different from the first height, and a first slope located between the first region and the second region.

2. The method of claim 1, wherein the first substrate is a quartz substrate.

3. The method of claim 1, wherein the first film includes a silicon (Si) element.

4. The method of claim 1, wherein the second film includes a chromium (Cr) element, a molybdenum (Mo) element, a tungsten (W) element, a gold (Au) element, a silver (Ag) element or a platinoid element, or includes an organic film.

5. The method of claim 1, wherein the etching rate of the second film by the chemical solution is smaller than the etching rate of the first substrate by the chemical solution.

6. The method of claim 1, further comprising forming, on the first substrate, a light-shielding film including a plurality of light-shielding patterns.

7. A method of manufacturing an original plate, comprising:
forming a resist film on a first substrate;
forming, on the resist film, a third slope located between a third region including the resist film and a fourth region not including the resist film; and
etching the first substrate using the resist film as a mask to form, on the first substrate, a first region having a first height, a second region having a second height different from the first height, and a first slope located between the first region and the second region.

8. The method of claim 7, wherein the third slope is formed on the resist film by exposing the resist film using a laser beam and developing the resist film after the exposure.

9. The method of claim 7, wherein the third slope is formed on the resist film by exposing the resist film using a first shot and a second shot having a dose different from a dose of the first shot and developing the resist film after the exposure.

10. The method of claim 9, wherein at least a portion of the third slope is formed on the resist film between the first shot and the second shot.

11. The method of claim 9, wherein the first shot and the second shot are different in size and separated from each other.

12. The method of claim 7, further comprising forming, on the first substrate, a light-shielding film including a plurality of light-shielding patterns.

13. An original prate to be used for exposing a second substrate having a fourth slope, the plate comprising:
a first substrate provided with a first slope having a width smaller than 1/M a width of the fourth slope where M is a reduction ratio of the exposure.

14. The plate of claim 13, wherein the first slope has a width smaller than 1/M the width of the fourth slope, and a height difference smaller than 1/M² a height difference of the fourth slope.

15. The plate of claim 14, wherein an inclination angle of the first slope when the width of the first slope is smaller than 1/M the width of the fourth slope and the height difference of the first slope is smaller than 1/M² the height difference of the fourth slope is larger than an inclination angle of the first slope when the width of the first slope is 1/M the width of the fourth slope and the height difference of the first slope is 1/M² the height difference of the fourth slope.

16. The plate of claim 13, further comprising a light-shielding film provided on the first slope and including a plurality of light-shielding patterns.
